(19) United States
(12) Patent Application Publication
(10) Pub. No.: US 2020/0075561 A1
(43) Pub. Date: Mar. 5, 2020

(54) SEMICONDUCTOR PACKAGE

(71) Applicants: JI HWANG KIM, CHEONAN-SI (KR); JONGBO SHIM, ASAN-SI (KR); WON IL LEE, HWASEONG-SI (KR); JANGWOO LEE, ASAN-SI (KR); YOUNG KUN JEE, CHEONAN-SI (KR)

(72) Inventors: JI HWANG KIM, CHEONAN-SI (KR); JONGBO SHIM, ASAN-SI (KR); WON IL LEE, HWASEONG-SI (KR); JANGWOO LEE, ASAN-SI (KR); YOUNG KUN JEE, CHEONAN-SI (KR)

(21) Appl. No.: 16/298,421

(22) Filed: Mar. 11, 2019

(30) Foreign Application Priority Data
Aug. 29, 2018 (KR) 10-2018-0101803

(51) Int. Cl. H01L 25/10; H01L 23/498; H01L 23/31; H01L 23/00; H01L 23/538

(52) U.S. Cl. CPC H01L 25/105; H01L 23/49827; H01L 23/5384; H01L 24/17; H01L 23/3121

(57) ABSTRACT

A semiconductor package includes a first substrate, a first semiconductor chip mounted on the first substrate, an interposer substrate and a chip package stacked on the first semiconductor chip, and a first molding layer encapsulating the first semiconductor chip and the chip package. The chip package includes a second semiconductor chip on the interposer substrate. The interposer substrate has a base layer consisting of silicon, a conductive pattern on a top surface of the base layer, and a through-electrode extending through the base layer and connected to the conductive pattern.

### PRIORITY STATEMENT

This U.S. nonprovisional application claims priority under 35 U.S.C § 119 to Korean Patent Application No. 10-2018-0101803 filed on Aug. 29, 2018 in the Korean Intellectual Property Office, the entire contents of which are hereby incorporated by reference.

### BACKGROUND

The present inventive concepts relate to semiconductor packages. More particularly, the present inventive concepts relate to multi-chip stack type of semiconductor packages such as a package-in-package.

A semiconductor package is provided to allow an integrated circuit chip to be readily incorporated into electronic products. In one type of semiconductor package, a semiconductor chip is mounted on a printed circuit board and bonding wires or bumps are used to electrically connect the semiconductor chip to the printed circuit board.

As the electronics industry continues to evolve, there is a demand for electronic products that offer higher performance while operating at higher speeds, and which are more compact. To meet this trend, there has recently been developed a packaging technology in which a plurality of semiconductor chips are combined in a single package. For example, a package-in-package (PIP) providing a stack of semiconductor chips has been developed by setting one semiconductor package in another.

When a number of semiconductor packages are combined in a single package, an interposer is typically provided to electrically connect the semiconductor packages to each other. The interposer may readily connect the semiconductor packages to each other and may increase the freedom in laying out wiring of the semiconductor packages.

### SUMMARY

According to the present inventive concepts, there is provided a semiconductor package comprising a first substrate, a first semiconductor chip mounted to the first substrate, an interposer stacked on the first semiconductor chip, a second semiconductor chip stacked on the interposer, and discrete bodies of molded material encapsulating the second semiconductor chip and encapsulating the first semiconductor chip on the first substrate, respectively. The interposer comprises a base layer consisting of silicon, a conductive pattern on a top surface of the base layer, and a through-electrode extending vertically through the base layer to the conductive pattern.

For example, there is provided a semiconductor package comprising a first substrate, a first semiconductor chip mounted on the first substrate, an interposer substrate and a chip package stacked on the first semiconductor chip, the chip package comprising a second semiconductor chip on the interposer substrate, and a first molding layer encapsulating the first semiconductor chip and the chip package. The interposer substrate comprises a base layer consisting of silicon, a conductive pattern on a top surface of the base layer, and a through-electrode penetrating the base layer and connected to the conductive pattern.

According to the present inventive concepts, there is also provided a semiconductor package comprising a first package comprising a first substrate, a first semiconductor chip mounted on the first substrate, and a first molding layer covering the first semiconductor chip on the first substrate, a second package comprising a second substrate, a second semiconductor chip mounted on the second substrate, and a second molding layer covering the second semiconductor chip on the second substrate, and an interposer between the first package and the second package. The interposer comprises a silicon base layer, a through-electrode extending vertically through the silicon base layer, and an electrical connector on a bottom surface of the silicon base layer. The first molding layer extends onto a lateral surface of the silicon base layer of the interposer and covers a lateral surface of the second molding layer.

According to the present inventive concepts, there is also provided a semiconductor package comprising a first substrate, a first semiconductor chip mounted on the first substrate, a second package comprising an interposer on the first semiconductor chip, and a second semiconductor chip mounted on the interposer, and a molding layer encapsulating the second package on the first substrate. The interposer comprises a base layer consisting of silicon, at least one through-electrode extending vertically through the base layer, and at least one electrical connector on a bottom surface of the base layer and coupled to the first substrate, the at least one electrical connector being in contact with the at least one through-electrode.

### BRIEF DESCRIPTION OF THE DRAWINGS

FIGS. 1, 2 and 3 are cross-sectional views of different versions of one example of a semiconductor package according to the present inventive concepts.

FIGS. 4 and 5 are cross-sectional views of different versions of another example of a semiconductor package according to the present inventive concepts.

FIGS. 6, 7, 8, 9, 10, 11 and 12 are cross-sectional views of a semiconductor package during the course of its manufacture and together illustrate an example of a method of fabricating a semiconductor package according to the present inventive concepts.

FIGS. 13, 14, 15, 16, 17, 18 and 19 are cross-sectional views of a semiconductor package during the course of its manufacture and together illustrate another example of a method of fabricating a semiconductor package according to the present inventive concepts.

### DETAILED DESCRIPTION

Examples of semiconductor packages according to the present inventive concepts, and examples of methods of manufacturing the same, will now be described in detail with reference to the accompanying drawings. Note, throughout the disclosure, a single element may be described or referred to but such a description or reference does not exclude the existence of other like elements particularly when a plurality of such elements are shown in the drawings.

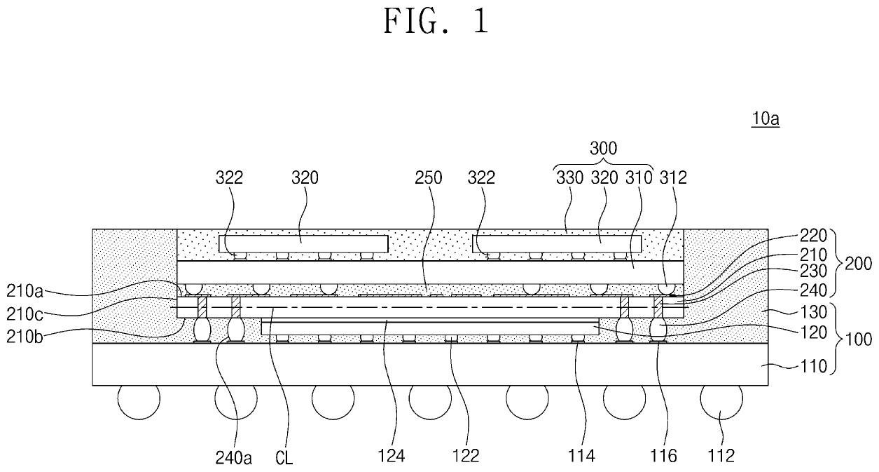

FIGS. 1 to 3 illustrate versions of a first example of a semiconductor package according to the present inventive concepts.

Referring to FIG. 1, a semiconductor package 10a has a package-in-package (PIP) structure. The semiconductor package 10a may include a first semiconductor chip 120 mounted on a first substrate 110, a chip package 300 provided on the first semiconductor chip 120, and a first molding layer 130 lying on the first substrate 110 and covering the first semiconductor chip 120 and the chip package 300. For purposes of description, a first package 100 may be defined to include the first substrate 110, the first semiconductor chip 120, and the first molding layer 130, and a second package 300 may refer to the chip package 300. The first molding layer 130 may be a discrete body of molded material. The second package 300 may be provided in the first molding layer 130 of the first package 100.

The first substrate 110 may have at least one insulating layer and wiring (conductive traces, pads, vias, for example) integral with the at least one insulating layer and providing conductive paths (not shown) between top and bottom surfaces of the at least one insulating layer. The first substrate 110 may include a printed circuit board (PCB). Alternatively, the first substrate 110 may have a structure in which at least one dielectric layer and at least one wiring line layer (layers of conductive traces) are alternately stacked. The first substrate 110 may have, at its top surface, first substrate pads 114 and second substrate pads 116.

External terminals 112 may be disposed below the first substrate 110. For example, the external terminals 112 may be disposed on terminal pads (not shown) provided at a bottom surface of the first substrate 110. The external terminals 112 may include solder balls or solder bumps, and the semiconductor package 10a may include one of a ball grid array (BGA), a fine ball grid array (FBGA), or a land grid array (LGA), based on the type of the external terminals 112.

The first semiconductor chip 120 may be mounted on the top surface of the first substrate 110. For example, the first semiconductor chip 120 may be flip-chip bonded to the first substrate pads 114 of the first substrate 110. The first semiconductor chip 120 may be electrically connected to the first substrate 110 through first chip terminals 122 such as solder balls or solder bumps. However, the present inventive concepts are not limited thereto. For example, bonding wires (not shown) may be used to mount the first semiconductor chip 120 on the first substrate 110. In this description, the phrase “electrically connected/coupled to” means either directly or indirectly electrically connected/coupled to. The first semiconductor chip 120 may be, for example, a logic chip or a memory chip. The memory chip may be, for example, a DRAM, NAND flash, NOR flash, PRAM, ReRAM, or MRAM.

However, the first semiconductor chip 120 need not be a memory chip. For example, the first semiconductor chip 120 may instead be an application processor, e.g., the first semiconductor chip 120 may be a logic chip. The first semiconductor chip 120 may be electrically connected through the first substrate 110 to the external terminals 112. FIG. 1 shows an example in which the semiconductor package has only one first semiconductor chip 120 but a plurality of the first semiconductor chips may be provided as disposed laterally relative to each other (at the same level) on the first substrate 110.

An interposer, referred to hereinafter as “interposer substrate 200” is provided on the first semiconductor chip 120. The interposer substrate 200 may include a base 210, a conductive pattern 220, a through-electrode 230, and a connector 240. The interposer substrate 200 will be further described in detail.

The base 210 includes silicon (Si) and may consist of a single layer of silicon (Si). Because the base 210 includes silicon whose thermal conductivity is high, heat generated from the first semiconductor chip 120 may be easily discharged through the interposer substrate 200. In addition, because silicon is a relatively rigid material, the interposer substrate 200 is not likely to warp to a significant extent when subjected to heat applied during fabrication processes or generated when the semiconductor package 10a is operated.

The conductive pattern 220 may be provided on a top surface 210a of the base 210. The conductive pattern 220 may be used as a redistribution (wiring) layer for the second package 300 which will be further discussed below. The conductive pattern 220 may is of a conductive material such as a metal.

The through-electrode 230 extends vertically in the base 210 and has the form of a plug or pillar. The through-electrode 230 may extend from a bottom surface 210b of the base 210 toward the top surface 210a of the base 210. The through-electrode 230 may have a top surface in contact with the conductive pattern 220. The through-electrode 230 may have a bottom surface exposed at the bottom surface 210b of the base 210. In examples of the present inventive concepts, the base of the interposer substrate 200 does not include a dielectric layer, and the base 210 of the interposer substrate 200 does not include conductive material or circuit lines (conductive traces) spread out or extending horizontally therein; thus, upper and lower portions of the base 210 may be of similar materials and have similar densities. To this end, the base 210 may be configured such that its upper and lower portions are symmetrical about its central line CL. Therefore, the interposer substrate 200 is not prone to becoming warped by heat applied during fabrication processes or generated when the semiconductor package 10a is operated. In addition, because the base 210 of the interposer substrate 200 does not include a dielectric layer, or conductive material or circuit line spread out or extending horizontally in the base 210, the base 210 may be relatively thin. Accordingly, the semiconductor package 10a may be relatively thin and compact.

The connector 240 may be provided on the bottom surface 210b of the base 210. When viewed in plan, the connector 240 may be aligned with the through-electrode 230. The connector 240 may be in contact with the through-electrode 230. The connector 240 may be electrically connected by the through-electrode 230 to the conductive pattern 220. A plurality of the connectors 240 may be used to mount the interposer substrate 200 on the second substrate pads 116 of the first substrate 110. For example, the connectors 240 may be provided between the base 210 and the first substrate 110, and when viewed in plan, may be disposed alongside the first semiconductor chip 120.

The second package 300 may be provided on the interposer substrate 200. The second package 300 may include a second substrate 310, second semiconductor chips 320, and a second molding layer 330. The second molding layer 330 may be a discrete body of molded material, i.e., a body of molded material discrete from the first molding layer 130.

The second substrate 310 may be provided on the interposer substrate 200. The second substrate 310 may be mounted on the conductive pattern 220 of the interposer substrate 200. Substrate terminals 312, such as solder balls or solder bumps, coupled to the conductive patterns 220 of the interposer substrate 200 may be provided on the bottom surface of second substrate 310. The second substrate 310 may be electrically connected to the interposer substrate 200 through the substrate terminals 312. The conductive patterns 220 of the interposer substrate 200 may redistribute the conductive paths provided by, for example, the first substrate 110, through-electrodes 230 and connectors 240, to the substrate terminals 312 of the second substrate 310. More generally, the conductive patterns 220 of the interposer substrate 200 may redistribute the signals from the first substrate 110 to the second semiconductor chips 320 and vice versa. The second substrate 310 may include a printed circuit board (PCB). Alternatively, the second substrate 310 may have a structure in which at least one dielectric layer and at least one wiring line layer are alternately stacked. An under-fill layer 250 may fill a space between the interposer substrate 200 and the second substrate 310. The under-fill layer 250 may be formed either of a flux containing a resin, an activator, and a solvent, or of a molding material. The solvent may include a glycol ether ester compound, a glycol ether compound, an ester compound, a ketone compound, or a cyclic ester compound.

The second semiconductor chips 320 may be mounted on a top surface of the second substrate 310. For example, the second semiconductor chips 320 may be mounted in a flip-chip bonding manner or a wire bonding manner. The second semiconductor chips 320 may be electrically connected to the second substrate 310 by second chip terminals 322 such as solder balls or solder bumps. The second semiconductor chips 320 may be logic chips or memory chips. The second semiconductor chips 320 may be electrically connected by the second substrate 310 to the interposer substrate 200. Although FIG. 1 shows an example in which the semiconductor package 10a has only two second semiconductor chips 320, only one or more than two second semiconductor chips 320 may be provided instead.

The second molding layer 330 may encapsulate the second semiconductor chips 320 on the second substrate 310. For example, the second molding layer 330 may cover top surfaces of the second semiconductor chips 320. The second molding layer 330 may include a dielectric polymeric material such as an epoxy molding compound (EMC). The second package 300 may have different configurations from that shown in and described above with reference to FIG. 1. For example, the second package 300 may be a chip stack package comprising a stack of chips.

The first molding layer 130 may be provided on the first substrate 110. The first molding layer 130 may encapsulate the first semiconductor chip 120. For example, the first molding layer 130 may fill spaces between the first substrate 110 and the first semiconductor chip 120 and between the first substrate 110 and the interposer substrate 200, the first molding layer 130 may cover a lateral surface of the first semiconductor chip 120, and the first molding layer 130 may cover lateral surfaces 240a of the connectors 240 of the interposer substrate 200. The lateral surfaces 240a of the connectors 240 may be in overall contact with the first molding layer 130. The first molding layer 130 may surround the second package 300. For example, the first molding layer 130 may extend from the first substrate 110 to a lateral surface of the interposer substrate 200, a lateral surface of the second substrate 310, and a lateral surface of the second molding layer 330, which lateral surface of the interposer substrate 200 corresponds to a lateral surface 210c of the base 210. The first molding layer 130 may cover the lateral surface 210c of the interposer substrate 200, the lateral surface of the second substrate 310, and the lateral surface of the second molding layer 330. Therefore, the first molding layer 130 may protect the interposer substrate 200 and the second substrate 310 against an impact applied laterally. As discussed above, the second package 300 may be disposed in the first molding layer 130 of the first package 100, and thus the semiconductor package 10a may have a package-in-package (PIP) structure.

Accordingly, the term “encapsulate” as used herein describes a relation in which the encapsulate covers sufficient surfaces of a chip or package to fix the chip or package in place and/or protect the same from external environmental conditions. That is, the term “encapsulate” does not imply that the encapsulant completely surrounds the object(s) it is encapsulating.

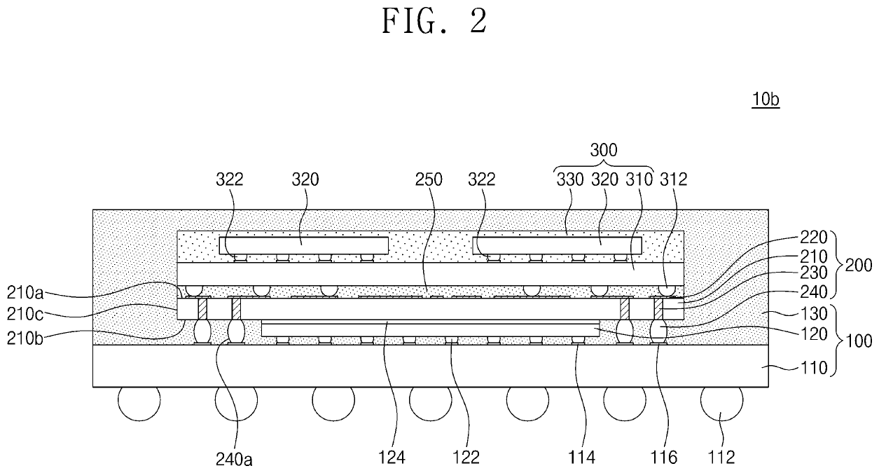

In the version shown in FIG. 2, the first molding layer 130 completely covers the second package 300. More specifically, the first molding layer 130 covers the lateral surface 210c of the interposer substrate 200, the lateral surface of the second substrate 310, the lateral surface of the second molding layer 330, and a top surface of the second molding layer 330. The second package 300 in this case is also disposed within the first molding layer 130 of the first package 100, which configuration also provides a PIP type semiconductor package 10b.

Referring back to FIG. 1, a thermal conductive layer 124 may be provided between the first semiconductor chip 120 and the interposer substrate 200. The thermal conductive layer 124 may be in contact with a top surface of the first semiconductor chip 120 and the bottom surface 210b of the base 210 of the interposer substrate 200. Heat generated from the first semiconductor chip 120 may be transferred through the thermal conductive layer 124 to the interposer substrate 200. The thermal conductive layer 124 may include a material whose thermal conductivity is high. For example, the thermal conductive layer 124 may be formed of a thermal interface material (TIM) such as thermal grease. The interposer substrate 200 may thus effectively radiate heat generated from the first semiconductor chip 120. The thermal conductive layer 124 may attach the first semiconductor chip 120 to the interposer substrate 200. As a result, the first semiconductor chip 120 and the interposer substrate 200 may be rigidly attached to enhance the structural stability of the semiconductor package 10a. The thermal conductive layer 124 is optional, though, i.e., is omitted in other versions of the semiconductor package according to the present inventive concepts. In some examples, the first semiconductor chip 120 contacts the base 210 of the interposer substrate 200. Alternatively, the first semiconductor chip 120 is spaced apart from the bottom surface 210b of the base 210, and the first molding layer 130 fills the space between the first semiconductor chip 120 and the base 210.

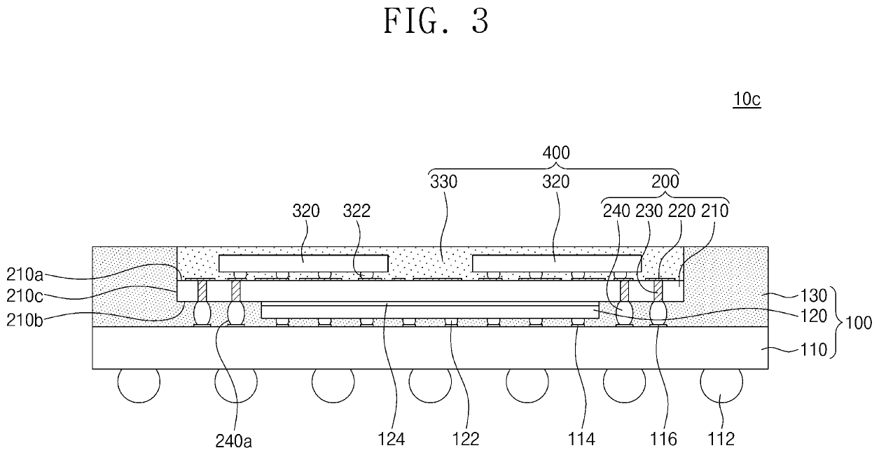

In certain versions of this example of a semiconductor package according to the present inventive concepts, the second substrate 310 is not provided. Such a version of a semiconductor package 10c will be described in detail in conjunction with FIG. 3. The second semiconductor chips 320 may be mounted on the interposer substrate 200. For example, the second semiconductor chips 320 may be coupled through the second chip terminals 322 to the conductive patterns 220 of the interposer substrate 200. In the version of FIG. 3, a second package 400 may be provided, which includes the interposer substrate 200, the second semiconductor chips 320, and the second molding layer 330. The interposer substrate 200 may redistribute the signals from the first substrate 110 to the second semiconductor chips 320 and vice versa.

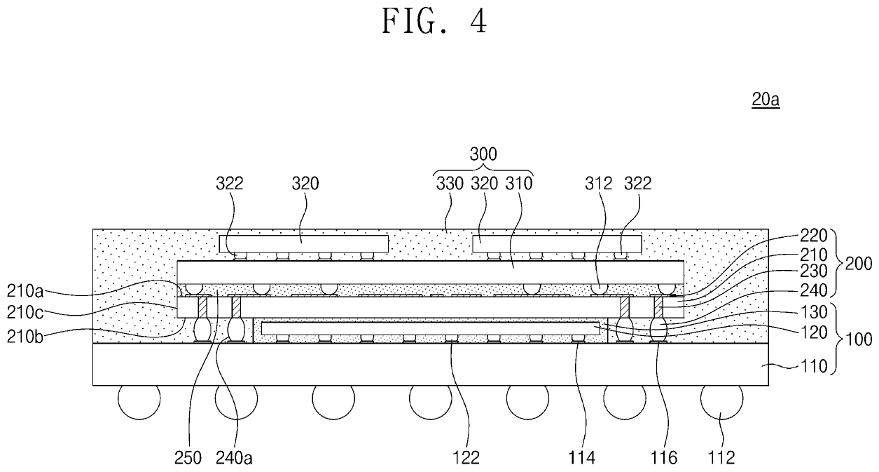

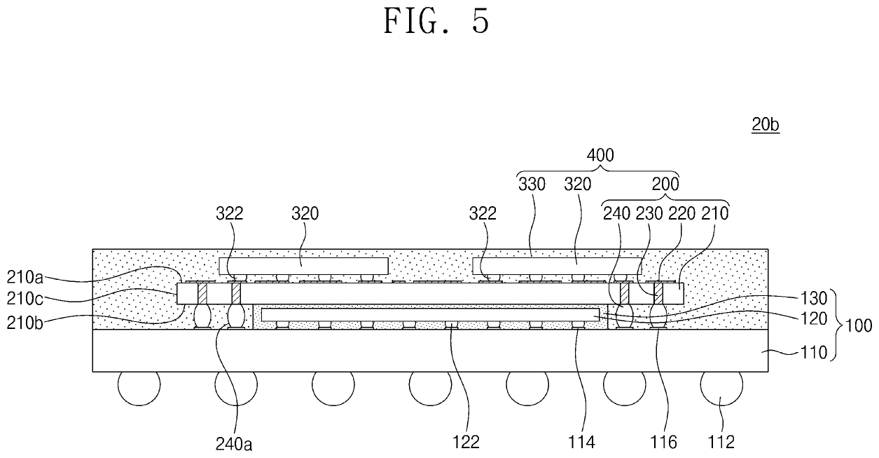

FIGS. 4 and 5 illustrate versions of another example of a semiconductor package according to the present inventive concepts. In the description that follows, components similar to those discussed with reference to FIGS. 1 to 3 are allocated the same reference numerals, and a detailed explanation thereof may be omitted or abridged for the sake of brevity.

Referring to FIG. 4, a semiconductor package 20a may include a first molding layer 130 covering a first semiconductor chip 120 on a first substrate 110 and also a chip package 300 provided on the first molding layer 130. The first substrate 110, the first semiconductor chip 120, and the first molding layer 130 may be covered with a second molding layer 330 (which will be discussed below) of the chip package 300. For purposes of description, a first package 100 may be defined to include the first substrate 110, the first semiconductor chip 120, and the first molding layer 130, and a second package may refer to the chip package 300.

The first substrate 110 may have, at its top surface, first substrate pads 114 and second substrate pads 116.

External terminals 112 may be disposed on terminal pads (not shown) provided on a bottom surface of the first substrate 110.

The first semiconductor chip 120 may be mounted on the top surface of the first substrate 110. The first semiconductor chip 120 may be flip-chip bonded or wire-bonded to the first substrate pads 114 of the first substrate 110. The first semiconductor chip 120 may be a logic chip or a memory chip.

The first substrate 110 may be provided thereon with the first molding layer 130 encapsulating the first semiconductor chip 120. For example, the first molding layer 130 may cover a top surface of the first semiconductor chip 120. The first molding layer 130 may partially expose the top surface of the first substrate 110. For example, the first molding layer 130 may expose the second substrate pads 116 of the first substrate 110. The first molding layer 130 may include a dielectric polymeric material such as an epoxy molding compound (EMC).

An interposer substrate 200 is provided on the first molding layer 130. The interposer substrate 200 may include a base 210, a conductive pattern 220, a through-electrode 230, and a connector 240. The base 210 includes silicon (Si) and may consist of a single layer of silicon (Si). The conductive pattern 220 may be provided on a top surface 210a of the base 210. The conductive pattern 220 may be used as a redistribution (wiring) layer for the second package 300. The through-electrode 230 may extend vertically in the base 210. The through-electrode 230 may extend from a bottom surface 210b of the base 210 toward the top surface 210a of the base 210. The through-electrode 230 may have a top surface in contact with the conductive pattern 220. The through-electrode 230 may have a bottom surface exposed at the bottom surface 210b of the base 210. The connector 240 may be provided on the bottom surface 210b of the base 210. The connector 240 may be in contact with the through-electrode 230. A plurality of the connectors 240 may be used to mount the interposer substrate 200 on the second substrate pads 116 of the first substrate 110.

The second package 300 may be provided on the interposer substrate 200. The second package 300 may include a second substrate 310, a second semiconductor chip 320, and a second molding layer 330.

The second substrate 310 may be mounted on the conductive pattern 220 of the interposer substrate 200. The second substrate 310 may be provided at its bottom with substrate terminals 312 coupled to the conductive patterns 220 of the interposer substrate 200. The conductive pattern 220 of the interposer substrate 200 may redistribute signals from the first substrate 110 to the second semiconductor chips 320 and vice versa.

A plurality of the second semiconductor chips 320 may be mounted on a top surface of the second substrate 310. For example, the second semiconductor chips 320 may be mounted in a flip-chip bonding manner or a wire bonding manner. The second semiconductor chips 320 may be logic chips or memory chips.

The second substrate 310 may be provided thereon with the second molding layer 330 encapsulating the second semiconductor chips 320. For example, the second molding layer 330 may cover top surfaces of the second semiconductor chips 320. The second molding layer 330 may cover a lateral surface 210c of the interposer substrate 200. In this configuration, the second molding layer 330 may protect the interposer substrate 200 and the second substrate 310 against an impact applied laterally. The second molding layer 330 may extend onto the first substrate 110. The second molding layer 330 may cover that part of the top surface of the first substrate 110 exposed by the first molding layer 130. The second molding layer 330 may extend between the interposer substrate 200 and the first substrate 110. Lateral surfaces 240a of the connectors 240 may be in overall contact with the second molding layer 330. The second molding layer 330 may be in contact with a lateral surface of the first molding layer 130. Therefore, the second package 300 may cover the first substrate 110, the first semiconductor chip 120, and the first molding layer 130. The second molding layer 330 may include a dielectric polymeric material such as an epoxy molding compound (EMC).

In another version of this example of a semiconductor package according to the present inventive concepts, the second substrate 310 is not provided. Such a semiconductor package 20b will now be described in detail in conjunction with FIG. 5. The second semiconductor chips 320 are mounted on the interposer substrate 200. For example, the second semiconductor chips 320 are coupled through second chip terminals 322 to the conductive patterns 220 of the interposer substrate 200. In the version of the semiconductor package shown in FIG. 5, a second package 400 may include the interposer substrate 200, the second semiconductor chips 320, and the second molding layer 330. The interposer substrate 200 may redistribute signals from the first substrate 110 to the second semiconductor chips 320.

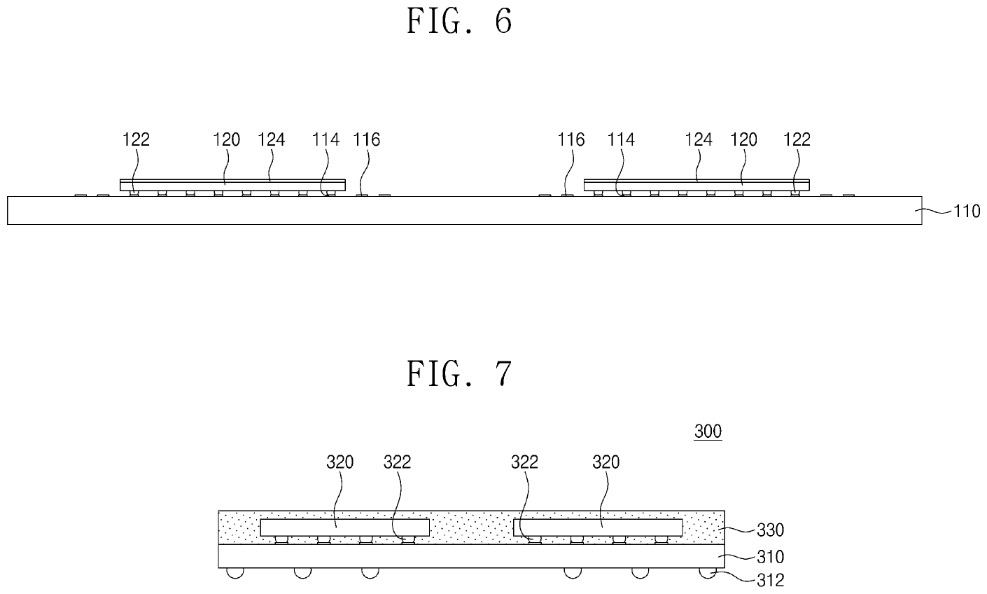

FIGS. 6 to 12 show a method of fabricating a semiconductor package according to the present inventive concepts.

Referring to FIG. 6, a first substrate 110 may be provided. The first substrate 110 may be a printed circuit board (PCB). The first substrate 110 may have, at its top surface, first substrate pads 114 and second substrate pads 116.

First semiconductor chips 120 may be mounted on the first substrate 110. The first semiconductor chips 120 may be flip-chip bonded to corresponding first substrate pads 114 of the first substrate 110. For example, the first semiconductor chips 120 may be oriented with their first chip terminals 122 facing the top surface of the first substrate 110. A reflow process may be performed on the first chip terminals 122, and thus the first semiconductor chips 120 may be mounted on the first substrate 110.

A thermal conductive layer 124 may be formed on a top surface of the first semiconductor chip 120. For example, the thermal conductive layer 124 may be formed by coating the top surface of the first semiconductor chip 120 with a thermal conductive material or may be provided in the form of a tape attached to the top surface of the first semiconductor chip 120. The thermal conductive layer 124 may include a thermal interface material (TIM) such as thermal grease.

Referring to FIG. 7, a second package 300 is provided. For example, second semiconductor chips 320 may be mounted on a second substrate 310. The second semiconductor chips 320 may oriented with their second chip terminals 322 facing a top surface of the second substrate 310. A reflow process may be performed on the second chip terminals 322, and thus the second semiconductor chips 320 may be mounted on the second substrate 310. The second substrate 310 may be provided with molding material so as to encapsulate the second semiconductor chips 320, and then cured to form a second molding layer 330. Substrate terminals 312 may be attached to the bottom of the second substrate 310.

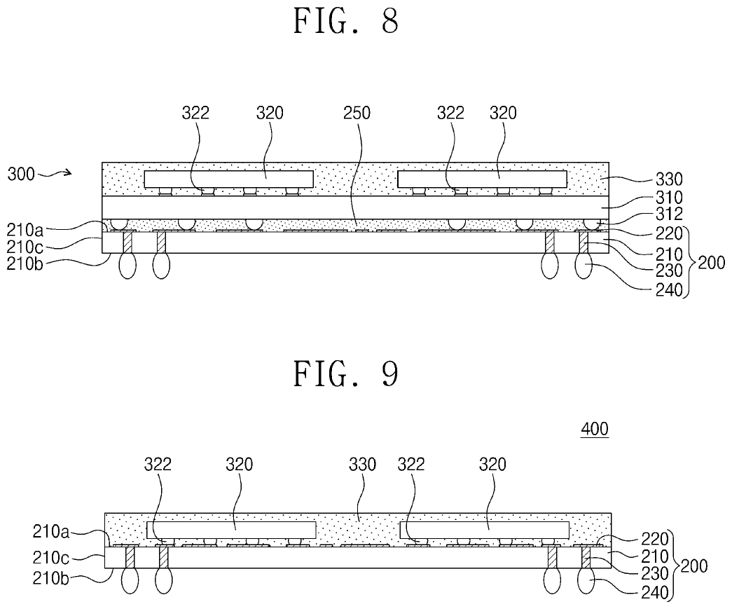

Referring to FIG. 8, an interposer substrate 200 is provided. For example, holes may be formed in a silicon base 210, and then filled with a conductive material to form through-electrodes 230. A conductive material may be deposited on a top surface 210a of the base 210, and then patterned to form conductive patterns 220.

The second package 300 may be mounted on the interposer substrate 200. For example, an under-fill material may be provided on a bottom surface of the second package 300, and then the substrate terminals 312 on the bottom surface of the second substrate 310 may be positioned to face a top surface of the interposer substrate 200. A reflow process may be performed on the substrate terminals 312, and thus the second package 300 may be mounted on the interposer substrate 200 with the substrate terminals 312 bonded to the conductive patterns 220. When the reflow process is performed, the under-fill material may be cured to form an under-fill layer 250. The under-fill material may include a flux material or a molding material.

In certain examples, after the second package 300 is mounted on the interposer substrate 200, the under-fill layer 250 is formed. For example, an under-fill material may be injected into a space between the interposer substrate 200 and the second substrate 310, and then cured to form the under-fill layer 250. In this case, a flux material or a molding material may be provided as the under-fill material injected into the space between the interposer substrate 200 and the second substrate 310. When a molding material is provided as the under-fill material, the under-fill material may include an ABF (Ajinomoto Build-up Film), a dielectric polymer such as an epoxy polymer, or a high molecular material such as a thermosetting resin.

Connectors 240 may be attached to the bottom of the interposer substrate 200. The connectors 240 may be attached to bottom surfaces of the through-electrodes 230, which bottom surfaces are exposed at a bottom surface 210b of the base 210.

The process discussed with reference to FIG. 6 may be preceded by the processes discussed with reference to FIGS. 7 and 8.

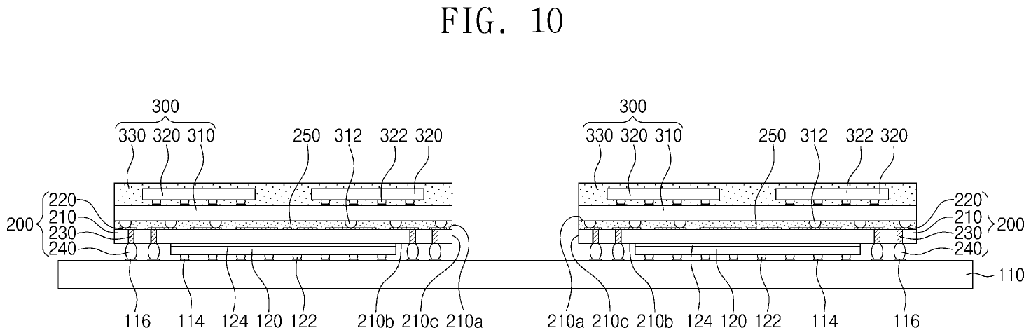

In certain examples, as shown in FIG. 9, the second package 400 is fabricated by mounting the second semiconductor chips 320 on the interposer substrate 200, and then forming on the interposer substrate 200 the second molding layer 330 to cover the second semiconductor chips 320. When the second package 400 is formed as discussed above, a semiconductor package 10c of FIG. 3 may be fabricated. An example in which the structure of FIG. 8 is used to form multiple ones of semiconductor packages will be described in detail with reference to FIGS. 10-12.

Referring to FIG. 10, a plurality of the resultant structures of FIG. 8 may be fabricated and mounted on the first substrate 110. For example, the connectors 240 of the interposer substrates 200 may be flip-chip bonded to corresponding second substrate pads 116 of the first substrate 110. The interposer substrates 200 may be disposed on corresponding first semiconductor chips 120, and the connectors 240 of the interposer substrates 200 may be disposed on sides of the first semiconductor chips 120.

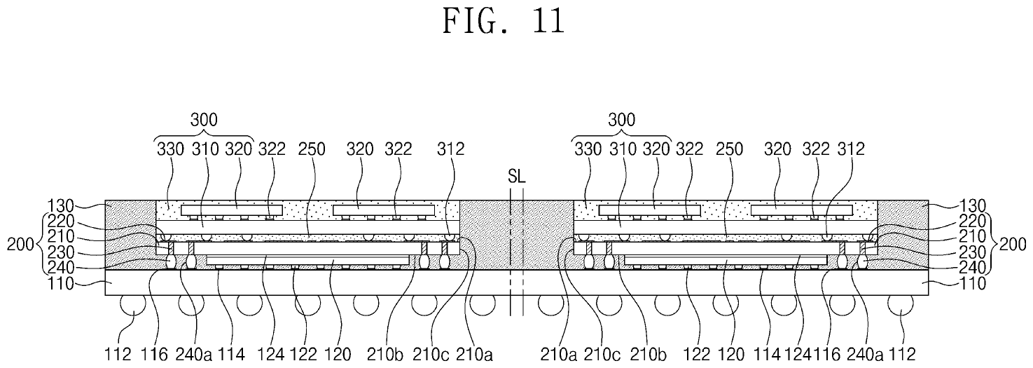

Referring to FIG. 11, a first molding layer 130 may be formed. For example, the first substrate 110 may be coated with the molding material so as to encapsulate the first semiconductor chips 120, and then cured to form the first molding layer 130. This process may comprise an injection molding process in which the molding material is injected into spaces between the first substrate 110 and the interposer substrates 200, and around the connectors 240. The molding material may be formed to cover lateral surfaces 210c of the interposer substrates 200 and lateral surfaces of the second packages 300.

According to an example of this, a bonding process may be followed by the molding process. For example, after the first semiconductor chips 120 and the interposer substrates 200 are mounted on the first substrate 110, the first molding layer 130 may be formed. In this case, the mounting process of the second packages 300 and the interposer substrates 200 may be terminated before the forming of the first molding layer 130. Therefore, when the interposer substrate 200 (or the second package 300) is mounted, it is not necessary to separately perform an etching process, such as a drilling process, in which the first molding layer 130 is etched to expose the second substrate pads 116 of the first substrate 110.

External terminals 112 may be attached to the bottom of the first substrate 110. For example, the external terminals 112 may be attached to terminal pads (not shown) disposed at a bottom surface of the first substrate 110. The external terminals 112 may include solder balls or solder bumps.

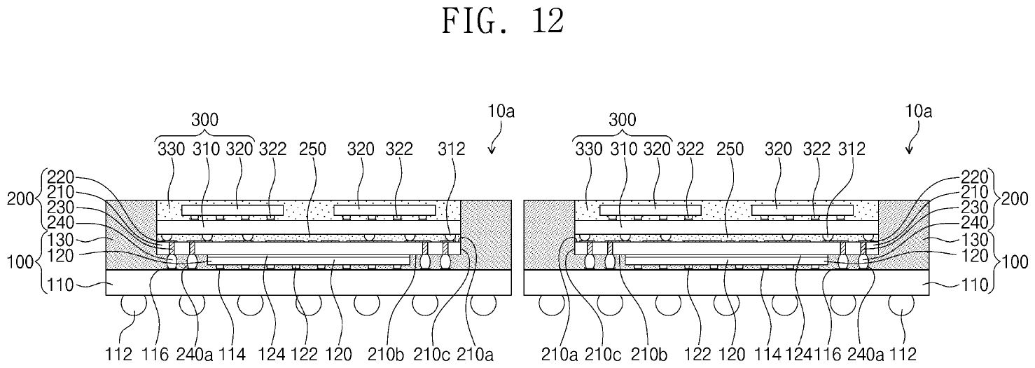

Referring to FIG. 12, the first substrate 110 and the first molding layer 130 may be cut to separate the first semiconductor chips 120 from each other, the interposer substrates 200 from each other, and the second packages 300 from each other. For example, the first substrate 110 and the first molding layer 130 may undergo a singulation process performed along a sawing line SL. The singulation process may be performed such that the first substrate 110 and the first molding layer 130 are diced into separate semiconductor packages 10a. The sawing line SL may run between the interposer substrates 200. Each of the semiconductor packages 10a may be configured substantially the same as the semiconductor package 10a of FIG. 1.

The interposer substrate 200 including the base 210 consisting of silicon is rather susceptible to being damaged by physical stress or shocks. For example, if a sawing process were directly performed on the interposer substrate 200, the sawing process could destroy the base 210 whose rigidity is high.

In contrast, according to the present inventive concepts, the interposer substrates 200 are horizontally spaced from each other, and not be cut during the singulation process. Therefore, the interposer substrate 200 is not subjected to the physical forces and stress caused by the singulation process and hence, the process of producing the semiconductor packages 10a has a low defect rate.

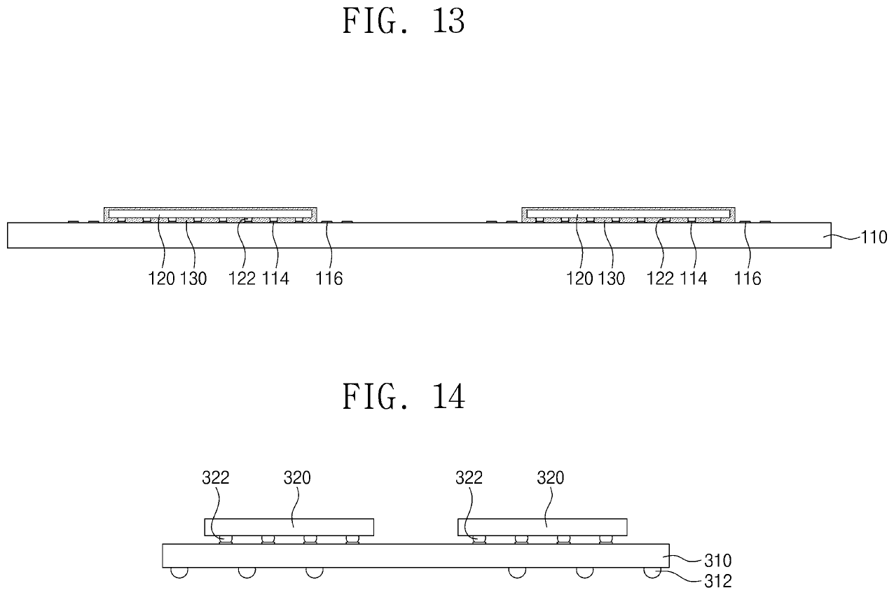

FIGS. 13 to 19 illustrate another method of fabricating a semiconductor package according to the present inventive concepts.

Referring to FIG. 13, a first substrate 110 is provided. The first substrate 110 may include a printed circuit board (PCB). The first substrate 110 may have, at its top surface, first substrate pads 114 and second substrate pads 116.

First semiconductor chips 120 may be mounted on the first substrate 110. The first semiconductor chips 120 may be flip-chip bonded to corresponding first substrate pads 114 of the first substrate 110. For example, the first semiconductor chips 120 may be oriented with their first chip terminals 122 facing the first substrate 110, and then a reflow process may be performed on the first chip terminals 122.

The first substrate 110 may be coated with a molding material so as to encapsulate the first semiconductor chips 120, and then cured to form first molding layers 130. The first molding layers 130 may encapsulate corresponding ones of the first semiconductor chips 120. The first molding layer 130 may partially expose the top surface of the first substrate 110. The second substrate pads 116 may be farther away than the first substrate pads 114 from the first semiconductor chips 120, and may not be covered with the first molding layers 130.

Referring to FIG. 14, a second substrate 310 is provided. The second substrate 310 may include a printed circuit board (PCB). The second substrate 310 may have, at its bottom surface, substrate terminals 312 such as solder balls or solder bumps.

Second semiconductor chips 320 may be mounted on the second substrate 310. The second semiconductor chips 320 may be flip-chip bonded to the second substrate 310. For example, the second semiconductor chips 320 may be oriented with their second chip terminals 322 facing the second substrate 310, and then a reflow process may be performed on the second chip terminals 322.

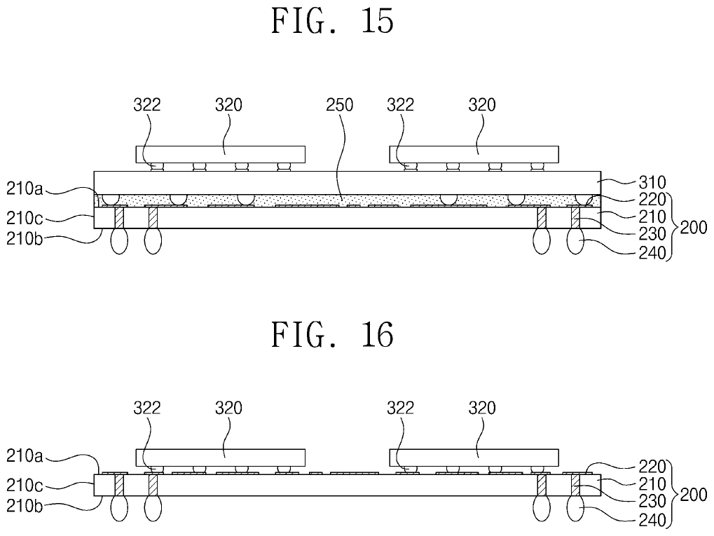

Referring to FIG. 15, an interposer substrate 200 is provided. For example, holes may be formed through a silicon base 210, and then filled with a conductive material to form through-electrodes 230. A conductive material may be deposited on a top surface 210a of the base 210, and then patterned to form conductive patterns 220.

The second substrate 310 may be mounted on the interposer substrate 200. For example, the second substrate 310 may be flip-chip bonded to the conductive patterns 220 of the interposer substrate 200. The second substrate 310 coated with an under-fill material may be oriented with its substrate terminals 312 facing the interposer substrate 200, and then a reflow process may be performed on the substrate terminals 312. When the reflow process is performed, the under-fill material may be cured to form an under-fill layer 250.

Connectors 240 may be attached to the bottom of the interposer substrate 200. The connectors 240 may be attached to bottom surfaces of the through-electrodes 230, which bottom surfaces are exposed at a bottom surface 210b of the base 210.

The process described with reference to FIG. 13 may be preceded by the processes shown in and described with reference to FIGS. 14 and 15.

In certain examples, as shown in FIG. 16, the second semiconductor chips 320 are mounted on the interposer substrate 200, and then a second molding layer (see 330 of FIG. 5) may be formed on the interposer substrate 200 so as to encapsulate the second semiconductor chips 320. When the second semiconductor chips 320 are directly mounted on the interposer substrate 200 as discussed above, the semiconductor package 20b of FIG. 5 may be fabricated. The following will discuss an example in which a structure of the type shown in FIG. 15 is formed.

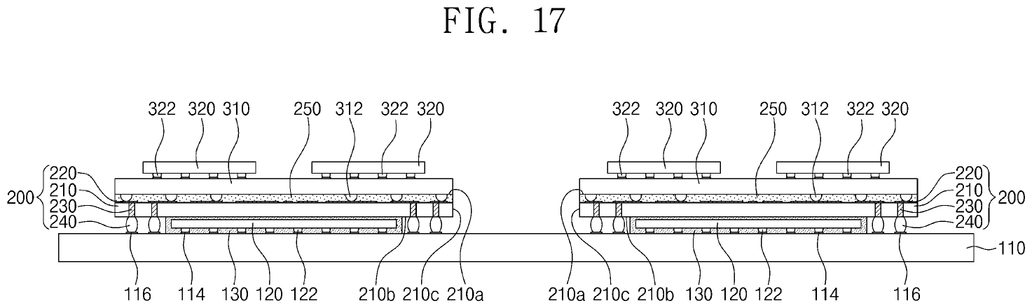

Referring to FIG. 17, a plurality of the resultant structures of FIG. 15 may be fabricated and mounted on the first substrate 110. For example, the connectors 240 of the interposer substrates 200 may be flip-chip bonded to corresponding second substrate pads 116 of the first substrate 110. The interposer substrates 200 may be disposed on corresponding first molding layers 130, and the connectors 240 of the interposer substrates 200 may be disposed on sides of the first molding layers 130. The bottom surfaces 210b of the base layers 210 of the interposer substrates 200 may be in contact with top surfaces of the first molding layers 130.

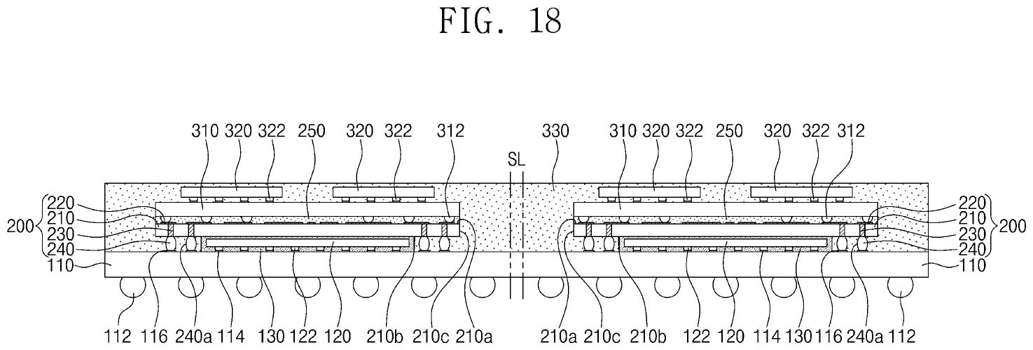

Referring to FIG. 18, a second molding layer 330 may be formed. For example, the second substrate 310 may be coated with a molding material so as to encapsulate the second semiconductor chips 320, and then cured to form the second molding layer 330. The molding material may cover the first substrate 110. For example, the molding material may be formed by an injection molding process in which the molding material coats lateral surfaces 210c of the interposer substrates 200, and is injected into spaces between the first substrate 110 and the interposer substrates 200. The molding material may surround the connectors 240 and contact the first molding layers 130.

External terminals 112 may be attached to the bottom of the first substrate 110. For example, the external terminals 112 may be attached to terminal pads (not shown) disposed at a bottom surface of the first substrate 110.

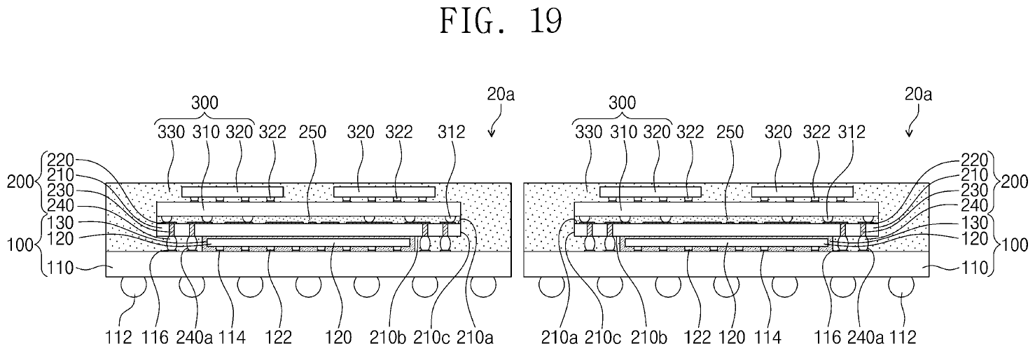

Referring to FIG. 19, the first substrate 110 and the second molding layer 330 may undergo a singulation process performed along a sawing line SL. The singulation process may be performed such that the first substrate 110 and the second molding layer 330 are diced into separate semiconductor packages 20a. The sawing line SL may run between the interposer substrates 200. Each of the semiconductor packages 20a may be configured substantially the same as the semiconductor package 20a of FIG. 4.

According to one aspect of the present inventive concepts, there is provided a semiconductor package in which heat is readily transferred through the interposer substrate from the first semiconductor chip and may thus undergo relatively warping due to the heat. In addition, the first molding layer may protect the interposer substrate and the second substrate against an impact applied laterally, and the first semiconductor chip and the interposer substrate may be rigidly adhered to enhance structural stability of the semiconductor package.

Furthermore, the base layer of the interposer substrate may be relatively thin. Thus, the semiconductor package may be relatively thin and compact.

Finally, the interposer substrate may be isolated from shock and other physical forces when a sawing process is performed. Thus, the semiconductor package lends itself to being manufactured by a method which has a high yield, i.e., semiconductor packages according to the present inventive concepts may be produced at a low rate of defects.

Although the present inventive concepts have been described in detail above in connection with certain examples thereof, such examples should be considered illustrative and not restrictive. That is, it will be understood by those of ordinary skill in the art that various changes in form and details may be made to the examples described above without departing from the spirit and scope of the present inventive concepts as defined by the appended claims.

What is claimed is:

1. A semiconductor package comprising:
a first substrate;
a first semiconductor chip mounted to the first substrate;
an interposer stacked on the first semiconductor chip;
a second semiconductor chip stacked on the interposer; and
discrete bodies of molded material encapsulating the second semiconductor chip and encapsulating the first semiconductor chip on the first substrate, respectively,
wherein the interposer comprises:
a base layer consisting of silicon;
a conductive pattern on a top surface of the base layer; and
a through-electrode extending vertically through the base layer to the conductive pattern.

2. The semiconductor package of claim 1, wherein the interposer further comprises an electrical connector between the base layer and the first substrate, the electrical connector being disposed beside the first semiconductor chip.

3. The semiconductor package of claim 2, wherein the electrical connector is in contact with the through-electrode.

4. The semiconductor package of claim 2, wherein one the discrete bodies of molded material comprises a molding layer filling a space between the first substrate and the base layer of the interposer, and a lateral surface of the electrical connector is overall in contact with the molding layer.

5. The semiconductor package of claim 1, wherein one of the discrete bodies of molded material covers a lateral surface of the base layer of the interposer and encapsulates the interposer on the first substrate.

6. The semiconductor package of claim 5, wherein said one of the discrete bodies of molded material is a first molding layer, and the other of the discrete bodies of molded material is a second molding layer encapsulating the second semiconductor chip on the interposer, a lateral surface of the second molding layer being covered by the first molding layer.

7. The semiconductor package of claim 1, further comprising:
a second substrate mounted on the interposer,
wherein the second semiconductor chip is mounted on a top surface of the second substrate.

8. The semiconductor package of claim 1, wherein a top surface of the first semiconductor chip is in contact with a bottom surface of the base layer of the interposer.

9. The semiconductor package of claim 1, wherein the first semiconductor chip is flip-chip bonded to the first substrate.

10. The semiconductor package of claim 1, further comprising:
a thermal conductive layer between the first semiconductor chip and the base layer of the interposer.

11. A semiconductor package, comprising:
a first package comprising a first substrate, a first semiconductor chip mounted on the first substrate, and a first molding layer covering the first semiconductor chip on the first substrate;
a second package comprising a second substrate, a second semiconductor chip mounted on the second substrate, and a second molding layer covering the second semiconductor chip on the second substrate; and
an interposer between the first package and the second package,
wherein the interposer comprises:
a silicon base layer;
a through-electrode extending vertically through the silicon base layer; and
an electrical connector on a bottom surface of the silicon base layer, and
wherein the first molding layer extends onto a lateral surface of the silicon base layer of the interposer and covers a lateral surface of the second molding layer.

12. The semiconductor package of claim 11, wherein the first substrate has a conductive pad at a top surface thereof, and the electrical connector is coupled to the first substrate at the conductive pad.

13. The semiconductor package of claim 12, wherein a lateral surface of the electrical connector is overall in contact with the first molding layer.

14. The semiconductor package of claim 11, wherein the second substrate has a terminal at a bottom thereof, and the electrical connector is electrically connected to the second substrate at the terminal.

15. The semiconductor package of claim 14, wherein the second molding layer extends between the silicon base layer of the interposer and the first substrate and is in contact with the lateral surface of the first molding layer.

16. The semiconductor package of claim 11, wherein the through-electrode is in contact with the electrical connector.

17. The semiconductor package of claim 11, wherein the interposer further comprises a conductive pattern on a top surface of the silicon base layer, and the through-electrode is electrically connected to the conductive pattern.

18. A semiconductor package, comprising:
a first substrate;
a first semiconductor chip mounted on the first substrate;
a package comprising an interposer on the first semiconductor chip, and a second semiconductor chip mounted on the interposer; and
a molding layer encapsulating the package on the first substrate,
wherein the interposer comprises:
a base layer consisting of silicon;
at least one through-electrode extending vertically through the base layer; and
at least one electrical connector on a bottom surface of the base layer and coupled to the first substrate, the at least one electrical connector being in contact with the at least one through-electrode.

19. The semiconductor package of claim 18, wherein the at least one electrical connector comprises a plurality of electrical connectors, and
when viewed in plan, the first semiconductor chip is disposed between respective groups of the plurality of electrical connectors.

20. The semiconductor package of claim 18, wherein the molding layer is a first molding layer, and the package further comprises:
a second molding layer covering the second semiconductor chip on the base layer of the interposer,
wherein the second molding layer has a lateral surface, and the first molding layer covers a lateral surface of the base layer of the interposer and the lateral surface of the second molding layer.
